(19) United States
(12) Patent Application Publication
(10) Pub. No.: US 2024/0005976 A1
(43) Pub. Date: Jan. 4, 2024

(54) ONE-CYCLE RECONFIGURABLE IN-MEMORY LOGIC FOR NON-VOLATILE MEMORY

(71) Applicants: Deliang Fan, Tempe, AZ (US); Shaahin Angizi, Orlando, FL (US)

(72) Inventors: Deliang Fan, Tempe, AZ (US); Shaahin Angizi, Orlando, FL (US)

(73) Assignee: Arizona Board of Regents on behalf of Arizona State University, Scottsdale, AZ (US)

(21) Appl. No.: 17/885,980

(22) Filed: Aug. 11, 2022

Related U.S. Application Data
(60) Provisional application No. 63/232,411, filed on Aug. 12, 2021.

(51) Int. Cl. G11C 11/16; H03K 19/20

(52) U.S. Cl. CPC G11C 11/1673; H03K 19/20; G11C 11/1657; G11C 11/161; G11C 11/1675

(57) ABSTRACT

A Processing-in-Memory (PIM) design is disclosed that converts any memory sub-array based on non-volatile resistive bit-cells into a potential processing unit. The memory includes the data matrix stored in terms of resistive states of memory cells. Through modifying peripheral circuits, the address decoder receives three addresses and activates three memory rows with resistive bit-cells (i.e., data operands). In this way, three bit-cells are activated in each memory bit-line and sensed simultaneously, leading to different parallel resistive levels at the sense amplifier side. By selecting different reference resistance levels and a modified sense amplifier, a full-set of single-cycle 1-/2-3-input reconfigurable complete Boolean logic and full-adder outputs could be intrinsically readout based on input operand data in the memory array.

### PRIORITY CLAIM

This application is a non-provisional conversion of, and claims the benefit of priority to U.S. Provisional Application Ser. No. 63/232,411 filed Aug. 12, 2021 entitled “ONE-CYCLE RECONFIGURABLE IN-MEMORY LOGIC FOR NON-VOLATILE MEMORY”, the disclosure of which is incorporated herein by reference in its entirety.

### GOVERNMENT SUPPORT

This invention was made with government support under 2005209, and 2003749 awarded by the National Science Foundation. The government has certain rights in the invention.

### FIELD OF THE DISCLOSURE

Generally, the present disclosure is directed to in-memory processing using non-volatile memory devices.

### BACKGROUND

Over the past decades, the amount of data required to be processed and analyzed by computing systems has been increasing dramatically to exascale. However, modern computing platforms' inability to deliver both energy-efficient and high-performance computing solutions leads to a gap between meets and needs. Unfortunately, such a gap will keep widening mainly due to limitations in architecture. For example, today's computers are based on the von-Neumann architecture, which includes separate computing and memory units connecting via buses, which leads to memory wall (including long memory access latency, limited memory bandwidth, energy-hungry data transfer) and huge leakage power for holding data in volatile memory.

Specifically, with the advent of high-throughput second generation parallel sequencing technologies, the process of generating fast and accurate large-scale data, such as genomics data, has become a significant advancement. For example, large-scale genomics data can enable measurement of the molecular activities in cells more accurately by analyzing the genomics activities, including mRNA quantification, genetic variants detection, and differential gene expression analysis. Thus, by understanding the transcriptomic diversity, phenotype predictions can be improved and provide more accurate disease diagnostics.

However, considering sequencing errors inherent to genomics, the reconstruction of full-length transcripts is a challenging task in terms of computation and time. Since the current cDNA sequencing technology cannot read whole genomes in one step, the data produced by the sequencer is extensively fragmented due to the presence of repeated chunks of sequences, duplicated reads, and large gaps. Thus, the goal of genome assembly process is to combine these large number of fragmented short reads and merge them into long contiguous pieces of sequence (i.e. contigs), to reconstruct the original chromosome from which the DNA is originated. An example of reconstruction of chromosomal DNA is illustrated in FIGS. 1A and 1B.

FIG. 1A is a schematic diagram of a de Bruijin graph-based genome assembly process. FIG. 1B illustrates a breakdown of execution time of the Meraculous genome assembler for a human and wheat data set.

Specifically, today's bioinformatics application acceleration solutions are mostly based on the von-Neumann architecture with separate computing and memory components connecting via buses, and inevitably consume a large amount of energy in data movement between them. In the last two decades, Processing-in-Memory (PIM) architecture, as a potentially viable way to solve the memory wall challenge, has been well explored for different applications. Especially, processing-in-non-volatile memory architecture has achieved remarkable success by dramatically reducing data transfer energy and latency. The key concept behind PIM is to realize logic computation within memory to process data by leveraging the inherent parallel computing mechanism and exploiting large internal memory bandwidth. Central Processing Unit (CPU)/Graphics Processing Unit (GPU)/Field Programmable Gate Array (FPGA), and even PIM-based efforts have focused on the DNA short read alignment problem, while the de novo genome assembly problem still relies mostly on CPU-based solutions. De novo assemblers are categorized into Overlap Layout Consensus (OLC), greedy, and de Bruijn graph-based designs.

Recently, de Bruijn graph-based assemblers have gained much more attention as they are able to solve the problem using Euler path in a polynomial time rather than finding Hamiltonian path in OLC-based assemblers as an NP hard problem. There are multiple CPU-based genome assemblers implementing the bi-directed de Bruijn graph model, such as Velvet, Trinity, etc. However, only a few GPU-accelerated assemblers have been presented, such as GPU-Euler. This mainly comes from the nature of the assembly workload that is not only compute-intensive but also extremely data-intensive requiring very large working memories. Therefore, adapting such problem to use GPUs with their limited memory capacities has brought many challenges. A graph-based genome assembly process, shown in FIG. 1A, as an illustrative example, basically consists of multiple stages, i.e., k-mer analysis for creating a Hashmap, graph construction and traversal, and scaffolding and gap closing. Further, FIG. 1B depicts the breakdown of execution time for the well-known Meraculous assembler for the human 104 and wheat 102 data sets. It is observed that Hashmap 106 and graph construction/traversal 108 are the two most expensive components, which together take over 80% of the total run time.

### SUMMARY

One-cycle reconfigurable in-memory logic for non-volatile memory is provided. In emerging resistive Non-Volatile Memories (NVM), such as Resistive RAM (ReRAM), Phase Change Memory (PCM), and Magnetic RAM (MRAM), the data are stored in terms of resistive states of memory cells. For a traditional NVM read operation, one selected memory cell will be activated and compared with a reference resistance through a memory Sense Amplifier (SA) to read out data value. Through modifying the memory peripheral circuits such as decoder and SA, systems and methods of the present disclosure propose a new architecture for a memory device that converts any NVM sub-array into a potential processing-in-memory unit.

In the proposed architecture, the modified address decoder receives three addresses and activates three memory rows with resistive bit-cells (i.e., data operands). As such, three bit-cells are activated in each memory bit-line and sensed simultaneously, leading to different parallel resistive levels at the sense amplifier side. By selecting different reference resistance levels in a modified SA, a full-set of single-cycle 1-/2-/3-input reconfigurable complete Boolean logic and full-adder outputs could be intrinsically read out based on input operand data in the memory array.

In various embodiments of the present disclosure, a non-volatile memory device for efficient in-memory processing of complete Boolean logic operations is provided, the non-volatile memory device can include a memory bank comprising a plurality of memory subarrays. Each memory subarray comprises a plurality of non-volatile memory cells storing a respective plurality of values, a modified row decoder, a SA comprising a plurality of sub-SAs, wherein the plurality of sub-SAs are respectively associated with a plurality of functions and a plurality of reference resistors. A memory subarray of the plurality of memory subarrays can be configured to compare, with one or more of the plurality of sub-SAs, one or more values of one or more respective non-volatile memory cells of the plurality of non-volatile memory cells with one or more of the plurality of reference resistors to obtain a processing output.

In another aspect of the present disclosure, a method for efficient in-memory processing of complete Boolean logic operations is provided. The method can include storing one or more values in one or more non-volatile memory cells of a plurality of non-volatile memory cells of a memory subarray of a non-volatile memory device, wherein the memory subarray comprises the plurality of non-volatile memory cells, a modified row decoder, a Sense Amplifier (SA) comprising a plurality of sub-SAs, wherein the plurality of sub-SAs are respectively associated with a plurality of functions, and a plurality of reference resistors. The method can also include comparing, using one or more of the plurality of sub-SAs of the memory subarray, the one or more values of with one or more of the plurality of reference resistors to obtain a processing output.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A and 1B illustrate examples of ([a) a de Bruijn graph-based genome assembly process, and (b) a breakdown of execution time of Meraculous genome assembler for human and wheat data-set;

FIG. 2A illustrates an example of Spin-Orbit Torque Magnetic Random Access Memory (SOT-MRAM) device structure and Spin Hall Effect;

FIG. 2B illustrates an example of schematic conditions of SOT-MRAM bit-cell;

FIG. 2C illustrates an table showing schematic conditions of SOT-MRAM bit-cell;

FIGS. 3A-3C illustrate an example architecture of the present disclosure, including Memory organization (FIG. 3A), Computational sub-array (FIG. 3B), and a new reconfigurable sense amplifier (FIG. 3C) of the present disclosure for implementation of a full-set of 2- and 3-input logic operations according to some embodiments of the present disclosure;

FIG. 4A illustrates an example of a reference comparison to realize in-memory operations according to some embodiments of the present disclosure;

FIG. 4B illustrates an example of a Monte-Carlo simulation of Vsense according to some embodiments of the present disclosure;

FIG. 5 illustrates an example of transient simulation wave-forms of sub-array(s) of the present disclosure and a reconfigurable SA for performing single-cycle in-memory operations according to some embodiments of the present disclosure;

FIG. 6 illustrates an example of genome assembly stages according to some embodiments of the present disclosure;

FIG. 7 illustrates an example of hash table generation from k-mers according to some embodiments of the present disclosure;

FIG. 8A illustrates an example of a proposed correlated data partitioning and mapping methodology for creating hash table(s) according to some embodiments of the present disclosure;

FIG. 8B illustrates an example of realization of parallel in-memory comparator (PANDA Cmp) between k-mers in a computational sub-array according to some embodiments of the present disclosure;

FIG. 9 illustrates an example of graph construction with sparse matrix with partitioning, allocation, and parallel computation according to some embodiments of the present disclosure;

FIG. 10 illustrates an example of in-memory addition and comparison scheme for finding the start vertex according to some embodiments of the present disclosure;

FIG. 11 illustrates an example of an evaluation framework developed for processing-in-memory platforms according to some embodiments of the present disclosure;

FIG. 12 illustrates an example of a breakdown of run time for under-test platforms running different k-mer-length genome assembly task according to some embodiments of the present disclosure;

FIG. 13 illustrates an example of breakdown of power consumption for PIM platforms running different k-mer-length genome assembly task compared to CPU according to some embodiments of the present disclosure

FIG. 14 illustrates an example of a trade-off between power consumption and run-time with regards to parallelism degree in k=25 according to some embodiments of the present disclosure;

FIG. 15A illustrates an example of the memory bottleneck ratio according to some embodiments of the present disclosure;

FIG. 15B illustrates an example of resource utilization ratio for CPU and three under-test PIM platforms for running genome assembly task according to some embodiments of the present disclosure;

FIG. 16 is a flowchart for a method for efficient in-memory processing of complete Boolean logic operations according to some embodiments of the present disclosure; and

FIG. 17 is a block diagram of a computing system including a memory device suitable for implementing efficient in-memory processing according to some embodiments of the present disclosure.

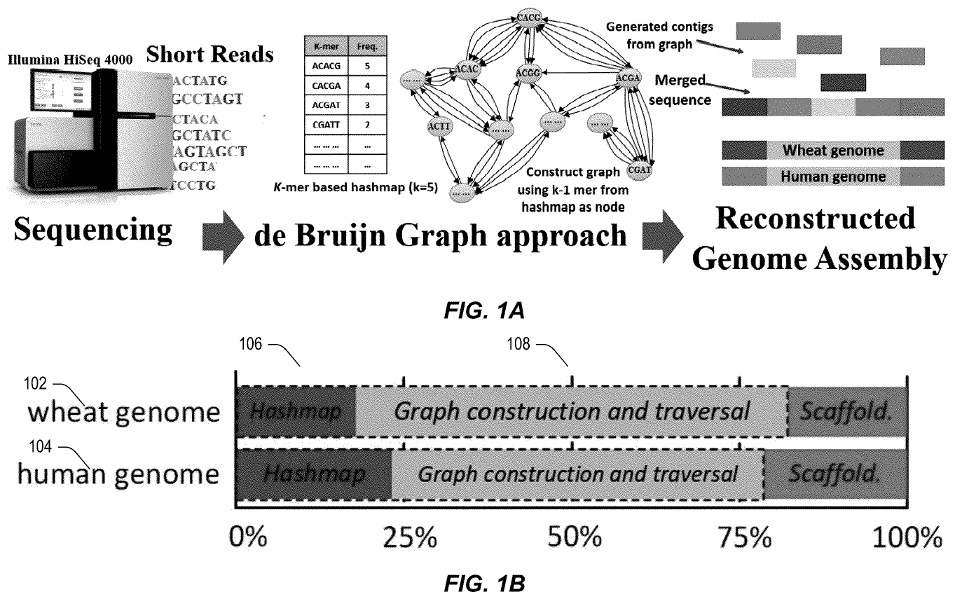

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Motivated by the aforementioned concerns, Processing-in-Memory (PIM) architecture, as a potentially viable way to solve the memory wall challenge, has been explored for various big data applications. In the big data processing era, many data-intensive applications such as Deep Learning, graph processing, Bioinformatics DNA alignment, etc., heavily rely on bulk bit-wise addition and comparison operations.

However, due to the intrinsic complexity of X(N)OR logic, the throughput of PIM platforms unavoidably diminishes when dealing with such bulk bit-wise operations. This is because these functions are constructed in a multi-cycle fashion, where intermediate data-write-back brings extra latency and energy consumption. Accordingly, the design of a single-cycle in-memory computing circuit capable of realizing various Boolean logic and full-adder outputs is crucial.

As such, systems and methods of the present disclosure propose a PIM design that converts any memory sub-array based on non-volatile resistive bit-cells into a potential processing unit. The memory includes the data matrix stored in terms of resistive states of memory cells. Through modifying peripheral circuits, the address decoder receives three addresses and activates three memory rows with resistive bit-cells (i.e., data operands). In this way, three bit-cells are activated in each memory bit-line and sensed simultaneously, leading to different parallel resistive levels at the sense amplifier side. By selecting different reference resistance levels and a modified sense amplifier, a full-set of single-cycle 1-/2-/3-input reconfigurable complete Boolean logic and full-adder outputs could be intrinsically readout based on input operand data in the memory array.

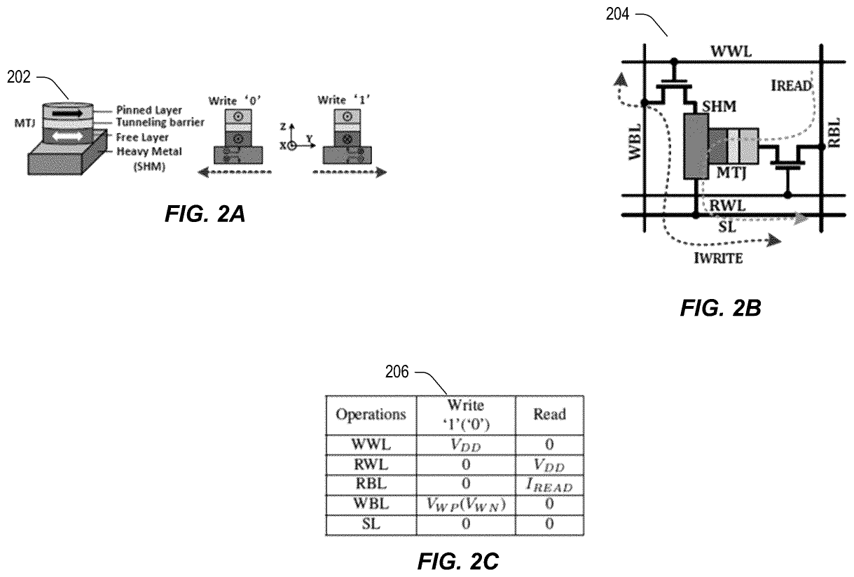

FIG. 2A illustrates an example of Spin-Orbit Torque Magnetic Random Access Memory (SOT-MRAM) device structure and Spin Hall Effect. FIG. 2B illustrates an example of schematic conditions of SOT-MRAM bit-cell. FIG. 2C illustrates an example of schematic conditions of SOT-MRAM bit-cell. As illustrated at FIG. 2A, the storage element 202 in SOT-MRAM is a composite device structure of a Spin Hall Metal (SHM) and Magnetic tunnel Junction (MTJ) (SHE-MTJ). The binary data is stored as resistance states of MTJ. Data-‘0’ (/‘1’) is encoded as the MTJ's lower(/higher) resistance or parallel(/anti-parallel) magnetization in both magnetic layers (free and fixed layers). Here the flow of charge current (±y) through the SHM (Tungsten, β−W) will cause accumulation of opposite directed spin on both surfaces of SHM due to spin Hall effect. Thus, a spin current flowing in ±z is generated and further produces spin-orbit torque (SOT) on the adjacent free magnetic layer, causing switch of magnetization. Each cell located in the computational sub-array is connected with a Write Word Line (WWL), Write Bit Line (WBL), Read Word Line (RWL) Read Bit Line (RBL), and Source Line (SL). The bit-cell structure 204 of 2T1R SOT-MRAM is illustrated at FIG. 2B, and the biasing conditions 206 of SOT-MRAM are illustrated at FIG. 2C.

An exemplary SA described herein consists of three sub-SAs with a total of four reference resistors. The controller unit could pick the proper reference using enable control bits (C_AND3, C_MAJ, C_OR3, C_M) to realize the memory read and a full set of 2- and 3-input logic functions.

The presented design could implement one-threshold in-memory operations (N)AND, (N)OR, etc. by activating multiple WLs simultaneously, and only by activating one SA's enable at a time, e.g., by setting C_AND3 to ‘1’, 3-input (N)AND logic can be readily implemented between operands located in the same bit-line. To implement 2-input logics, two rows initialized by ‘0’/‘1’ are considered in every sub-array such that 2-input functions can be made out of 3-input functions. For addition operation, by activating three memory rows simultaneously, OR3, Majority, and AND3 functions can be readily realized through three sub-SAs, respectively.

Each SA compares the equivalent resistance of parallel-connected input cells and their cascaded access transistors with a programmable reference by SA (R_OR3/R_MAJ/R_AND3). The proposed SA shows when the majority function of three inputs is ‘0’, the Sum output of the full-adder can be implemented by the OR3 function, and when the majority function is ‘1’, Sum can be achieved through the AND3 function. This behavior can be implemented by a multiplexer circuit after sub-SAs in a single cycle. The carryout of the full-adder can also be produced by the Majority function in the same memory cycle.

In some embodiments, a non-volatile memory device for efficient in-memory processing of complete Boolean logic operations is proposed. The non-volatile memory device includes a memory bank comprising a plurality of memory subarrays. Each memory subarray includes a plurality of non-volatile memory cells storing a respective plurality of values. Each memory subarray includes a modified row decoder. Each memory subarray includes a sense amplifier (SA) comprising a plurality of sub-SAs, wherein the plurality of sub-SAs are respectively associated with a plurality of functions. Each memory subarray includes a plurality of reference resistors. A memory subarray of the plurality of memory subarrays is configured to compare, with one or more of the plurality of sub-SAs, one or more values of one or more respective non-volatile memory cells of the plurality of non-volatile memory cells with one or more of the plurality of reference resistors to obtain a processing output.

In some embodiments, the plurality of functions comprise one or more of a read function, a NOR function, a OR function, a AND function, a NAND function; a XOR function, a XNOR function, a MAJ function, a MIN function, a READ function, or a SUM function.

In some embodiments, the memory bank comprises a control unit configured to select the one or more of the plurality of reference resistors using a plurality of control bits.

In some embodiments, the memory bank comprises one or more Read Word Lines (RWLs). In some embodiments, prior to comparing the one or more values, the memory subarray is configured to simultaneously activate, with the modified row decoder, at least one of the one or more RWLs to obtain the one or more values of the one or more non-volatile memory cells.

In some embodiments, a first sub-SA of the one or more sub-SAs is associated with a 3-input OR function, a second sub-SA of the one or more sub-SAs is associated with a 3-input AND function, a third sub-SA of the one or more sub-SAs is associated with a 3-input MAJORITY function, and the processing output comprises an addition output or a subtraction output.

In some embodiments, the processing output comprises a SUM output and a CARRY output, the third sub-SA is configured to generate the carry output, the first sub-SA is configured to generate the SUM output when the CARRY output is 0, and the second sub-SA is configured to generate the SUM output when the CARRY output is 1.

In some embodiments, each of a subset of memory cells from the plurality of non-volatile memory cells comprises a value of 1, and the one or more values comprise three values for three respective memory cells, wherein one of the three respective memory cells is a memory cell from the subset of memory cells.

In some embodiments, a sub-SA of the one or more sub-SAs is associated with a two-input XNOR function and/or a three-input XOR function.

In some embodiments, the memory subarray is configured to compare the one or more values within a single memory cycle of the memory bank.

In some embodiments, the plurality of non-volatile memory cells comprises a plurality of Magnetic Random Access Memory (MRAM) cells.

In some embodiments, the memory device comprises a Spin-Orbit Torque Magnetic Random Access Memory (SOT-MRAM) device.

In this disclosure the magnetization dynamics of Free Layer (m) are modeled by LLG equation with spin-transfer torque terms, which can be mathematically described as:

$$\frac{d m}{dt} = - \vert γ \vert m \times {H}_{eff} + α ( m \times \frac{d m}{dt} ) + \vert γ \vert β ( m \times {m}_{p} \times m ) - \vert γ \vert β {ϵ}^{′} ( m \times {m}_{p} )$$

$$β = \vert \frac{ℏ}{2 {μ}_{0} e} \vert \frac{{I}_{c} P}{{A}_{MTJ} {t}_{FL} {M}_{s}}$$

where ℏ is the reduced plank constant, γ is the gyromagnetic ratio, I_{c} is the charge current flowing through MTJ, t_{FL} is the thickness of free layer, ∈′ is the second Spin transfer torque coefficient, and H_{eff} is the effective magnetic field, P is the effective polarization factor, A_{MTJ} is the cross sectional area of MTJ, mₚ is the unit polarization direction. Note that the ferromagnets in MTJ have In-plane Magnetic Anisotropy (IMA) in x-axis. With the given thickness (1.2 nm) of the tunneling layer (MgO), the Tunnel Magneto-Resistance (TMR) of the MTJ is ˜171.2%

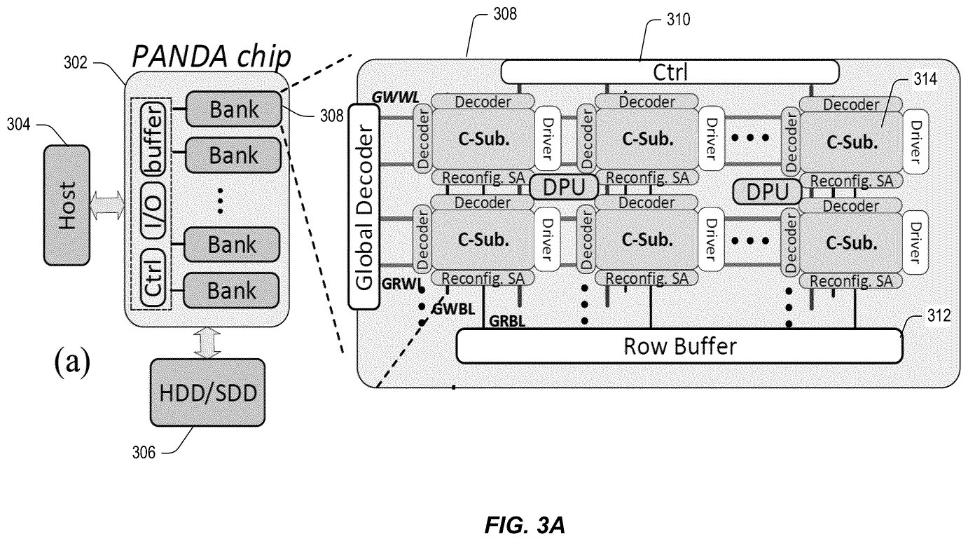

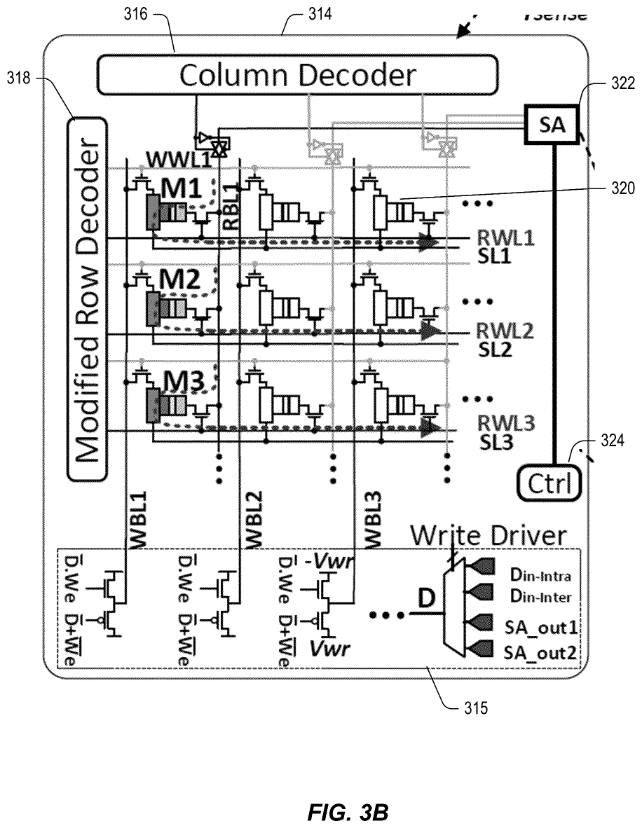

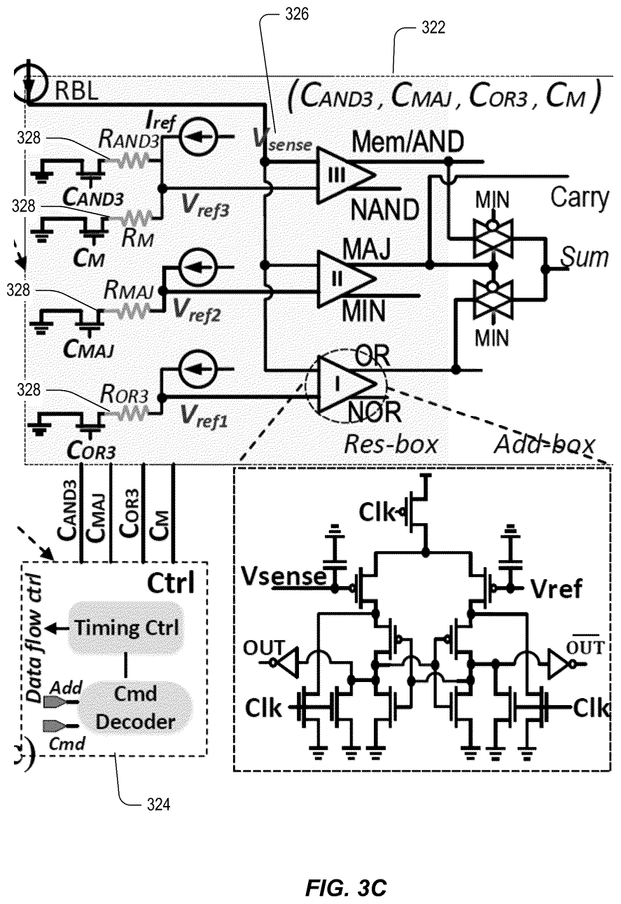

FIGS. 3A-3C illustrate an example platform architecture for in-processing non-volatile memory according to some aspects of the present disclosure. It should be noted that although the illustrated example architecture of FIGS. 3A-3C are depicted based on typical SOT-MRAM hierarchy, systems and methods of the present disclosure are not limited to such a hierarchy. As illustrated in (a) of FIG. 3A, each memory chip 302 consists of multiple memory banks 308 divided into 2D sub-arrays 314 of SOT-MRAM cells 320 (FIG. 3C). The memory chip 302 can be communicably coupled to a host 304 and an HDD/SDD 306. Each memory bank 308 can include the sub-arrays 314 if SOT-MRAM cells 320, and also include a controller 310 and a row bufffer 312. Modifications are applied on the sub-array level so that the sub-array(s) are reconfigurable to support both memory operation and in-memory bit-line computation. As depicted in FIG. 3B, the computational memory sub-array 314 (C-Sub.) of the present disclosure includes a modified memory row decoder 318, column decoder 316, write driver 315, and reconfigurable Sense Amplifier (SA) 322. The data-parallel intra-sub-array computation of sub-array is timed and controlled using a Controller 324 (ctrl) w.r.t. the physical address of operands.

Specifically, the architecture of FIGS. 3A-3C is designed to support bulk bit-wise operations between operands stored in each BL. Therefore, the in-memory computational throughput is solely limited by the physical memory row size i.e. 4 KB/8 KB in modern main memory chips. Digital Processing Units (DPU) are also shared between computational sub-arrays to handle nonparallel computational load of the platform.

The architecture illustrated in FIGS. 3A-3C is capable of performing a plurality of various processing-in-memory functions.

### Processing in Memory Functions

### Write Operations

To write ‘0’ (/‘1’) in a cell, e.g. in the cell of 1 st column and 2nd row (e.g., M2 in(b) of FIG. 3), the associated write driver first pulls WBL1 to negative (/positive) write voltage. This will provide a preset charge current flow from −V_{wr} to GND (/+V_{wr} to GND) that eventually changes the cell's resistance to Low-Rₚ/(High-R_{AP}).

### Reference Selection and Bit-Line Computing

The example architecture illustrated in FIGS. 3A-3C leverages the reference selection and bit-line computing method on top of a novel reconfigurable SA design demonstrated in FIG. 3C to handle memory read and in-memory computation. A purpose of reference selection is to simultaneously compare the resistance state of selected SOT-MRAM cell(s) with one or multiple reference resistors 328 in SA(s) to generate the results. The illustrated SA 322 comprises three sub-SAs (e.g., sub-SA 326) with a total of four reference resistors 328. In other embodiments, the SA 322 can comprise any number of sub-SAs. The controller 324 could pick the proper reference using enable control bits (C_{AND3}, C_{MAJ}, C_{OR3}, C_{M}) to realize the memory read and a full-set of 2- and 3-input logic functions, as tabulated in the following table:

| Operations | C_{AND3} | C_{MAJ} | C_{OR3} | C_{M} | Active SA | Row Init. |
|---|---|---|---|---|---|---|
| Read | 0 | 0 | 0 | 1 | SA-III | No |
| (N)AND3/ | 1 | 0 | 0 | 0 | SA-III | No/Yes |
| (N)AND2 | | | | | | |
| (N)OR3/ | 0 | 0 | 1 | 0 | SA-I | No/Yes |
| (N) OR2 | | | | | | |
| X(N)OR2 | 1 | 1 | 1 | 0 | SA-I-II-III | Yes |
| Maj | 0 | 1 | 0 | 0 | SA-II | No |
| (Carry)/Min | | | | | | |
| XOR3 | 1 | 1 | 1 | 0 | SA-I-II-III | No |
| (Sum) | | | | | | |

As depicted in FIG. 3C, the sense circuit is designed and tuned based at least in part on StrongARM latch. Each read/in-memory computing operation requires two clock phases: pre-charge (Clk ‘high’) and sensing (Clk‘low’). For instance, to realize the readoperation, the memory row decoder 318 first activates the corresponding RWL, then a small sense current (Isense) flows from the selected cell to ground, and generates a sense voltage (Vsense) at the input of SA-III. This voltage is accordingly compared with the memory mode reference voltage activated by C_{M} (Vsense,P<Vref,M<Vsense,AP).

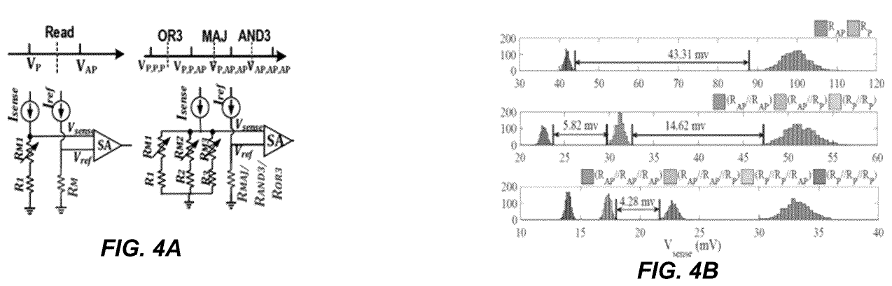

FIG. 4A illustrates an example of a reference comparison to realize in-memory operations. FIG. 4B illustrates an example of a Monte-Carlo simulation of Vsense. The SA-III produces high (/low) voltage if the path resistance is higher (/lower) than R_{M} (memory reference resistance), i.e. R_{AP}(/R_{P}). The architecture illustrated in FIGS. 3A-3C can implement one-threshold in-memory operations ((N)AND, (N)OR, etc.) by activating multiple RWLs simultaneously, and only by activating one SA's, can enable at a time e.g. by setting C_{AND3} to ‘1’, 3-input AND/NAND logic can be readily implemented between operands located in the same bit-line. To implement 2-input logics, two rows initialized by ‘0’/‘1’ are considered in every sub-array such that functions can be made out of 3-input functions.

### Addition

The architecture illustrated in FIGS. 3A-3C is enhanced with a circuit design that allows single-cycle implementation of addition/subtraction (add/sub) operation quite efficiently. By activating three memory rows at the same time (RWL1, RWL2, and RWL3 as illustrated by FIG. 3B, etc.), OR3, Majority (MAJ) and AND3 functions can be readily realized through SA-I, SA-II, and SA-III of FIG. 3C, respectively. Each SA compares the equivalent resistance of parallel connected input cells and their cascaded access transistors with a programmable references by SA (R_{OR3}/R_{MAJ}/R_{AND3}).

FIG. 4A illustrates an example voltage comparison between Vsense and Vref to realize these functions. While there are several addition-in-memory designs in non-volatile memory domain, they typically apply a large circuitry after SA to realize a multi-cycle design. In order to implement a single-cycle addition operation, the full-adder Boolean expression is reformulated to make it PIM-friendly. When the majority function of three input is 0, the Sum can be implemented by OR3 function and when majority function is 1, Sum can be achieved through AND3 function. This behavior can be implemented by a multiplexer circuit shown in Add-box depicted by FIG. 3C. The Boolean logic of such in-memory addition function is written as

$$Carry = AB + A C + BC = Maj ( A , B , C ) \qquad ( 3 )$$

$$\begin{matrix}Sum = ( \overline{( AB + A C + BC )} . ( A + B + C ) ) + \\ ( ( AB + A C + BC ) . ( ABC ) ) \\ = Maj ( A , B , C ) . OR ( A , B , C ) + MAJ ( A , B , C ) . AND ( A , B , C ) \\ = Carry . OR ( A , B , C ) + Carry . AND ( A , B , C )\end{matrix} \qquad ( 4 )$$

The carry-out of the full-adder can be directly produced by MAJ function by setting C_{MAJ} to ‘1’ in a single memory cycle, which is depicted as “Carry” in (c) of FIG. 3. For MAJ operation, R_{MAJ} is set at the midpoint of R_{P}//R_{P}//R_{AP} (‘0’, ‘0’, ‘1’) and R_{P}//R_{AP}//R_{AP} (‘0’, ‘1’, ‘1’), as depicted in FIG. 4A. Assuming M1, M2, and M3 operands, as depicted in FIG. 3B, the architecture of the present disclosure can generate Carry-MAJ and Sum-XOR3 in-memory logics in a single memory cycle. The ctrl's configuration for such add operations is described in the previously described table.

### Comparison

The architecture of the present disclosure offers a single-cycle implementation of XOR3 in-memory logic (Sum). To realize the bulk bit-wise comparison operation based on XNOR2, one memory row in each sub-array of the architecture is initialized to ‘1’. In this way, XNOR2 can be readily implemented out of XOR3 function. Therefore, every memory sub-array can potentially perform parallel comparison operation without need to external add-on logic or multi-cycle operation.

### Performance Analysis

### Functionality

To verify the circuit functionality of the sub-arrays of the present disclosure, a SOT-MRAM cell is first modeled by jointly applying the Non-Equilibrium Green's Function (NEGF) and Landau-Lifshitz-Gilbert (LLG) with spin Hall effect equations. Next, a Verilog-A model of 2-transistor 1-resistor SOT-MRAM device is developed with parameters listed in the following table to co-simulate with other peripheral CMOS circuits. A 45 nm North Carolina State University (NCSU) Product Development Kit (PDK) library is utilized for circuit analysis.

| Parameter | Value | |
|---|---|---|
| Free layer dimension (W × L × t)_{FL} | 60 × 40 × 2 | nm³ |
| SHM dimension | 60 × 80 × 2 | nm³ |
| Demagnetization Factor, Dₓ; D_{y}; D_{z} | 0.066; 0.911; 0.022 | |
| Spin flip length, λₛₕ | 1.4 | nm |
| Spin hall angle, θₛₕ | 0.3 | |
| Gilbert Damping Factor, α | 0.007 | |
| Saturation Magnetization, Mₛ | 850 | kA/m |
| Oxide thickness, tₒₓ | 1.2 | nm |
| RA product, RAₚ/TMR | 10.58 Ω · μm²/171.2% | |
| Supply voltage | 1 | V |
| CMOS technology | 45 | nm |
| SOT-MRAM cell area | 69 | F² |
| Access transistor width | 4.5 | F |

| | |
|---|---|
| Cell aspect Ratio | 1.91 |

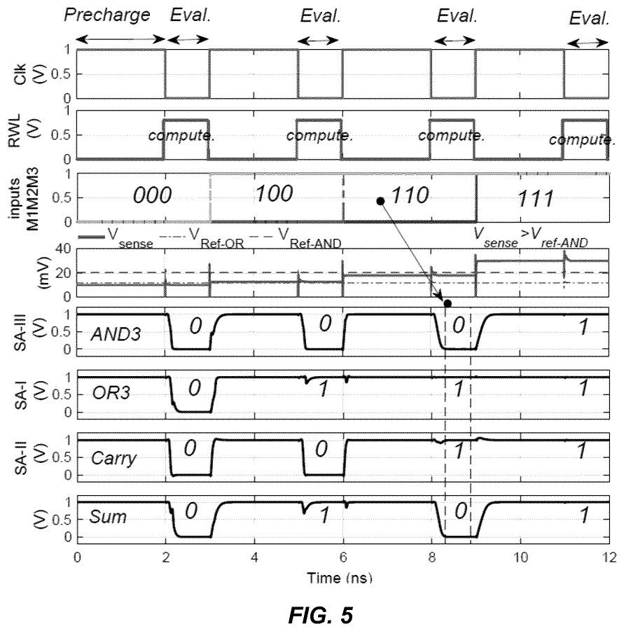

FIG. 5 illustrates an example of transient simulation wave-forms of sub-array(s) of the present disclosure and a reconfigurable SA for performing single-cycle in-memory operations according to some embodiments of the present disclosure. The transient simulation result of a single 256×256 sub-array is shown in FIG. 5. M1, M2, and M3 are taken as three SOT-MRAM cells located in the first column as the inputs for evaluation. Here, four input combination scenarios are considered for the write operation, as indicated by 000, 100, 110, and 111 in FIG. 5. For the sake of clarity of wave-forms, a 3 ns period clock is assumed that synchronises the write and read operation. However, a 2 ns period can be used for a reliable read and in-memory computation.

During the precharge phase of SA (Clk=1), ±Vwrite voltage is applied to the WBL to change the MRAM cell resistance to Rlow=5.6 kΩ or Rhigh=15.17 kΩ. Prior to the evaluation phase (Eval.) of SA, WWL and WBL is grounded while RBL is fed by the very small sense current, Isense=3 μA. In the evaluation phase, RWL goes high and depending on the resistance state of parallel bit-cells and accordingly SL, Vsense is generated at the first input of SAs, when Vref is generated at the second input of SAs. The voltage comparison between Vsense and Vref for AND3 and OR3 and the output of SAs are plotted in FIG. 5. For example, it is observed that only when Vsense>Vref,AND (M1M2M3=111), the SA-III outputs binary ‘1’, whereas output is ‘0. FIG. 5 also shows the in-memory XOR3 function (Sum) accomplished in a single memory cycle through three SA outputs.

### Reliability

The variation tolerance is assessed in the proposed sub-array and SA circuit by running a rigorous Mont-Carlo simulation. The simulation is run for 10000 iterations considering two source of variations in SOT-MRAM cells, first σ=5% process variation on the Tunneling MagnetoResistive (TMR) and second a σ=2% variation on the Resistance-Area product (RAP). The results illustrated in (b) of FIG. 4 proves that the sense margin reduces by increasing the number of selected input cells for in-memory operations. This can be alleviated by increasing the oxide thickness tₒₓ of SHE-MTJ. In this way, the tₒₓ was increased from 1.5 nm to 2 nm. This increased the sense margin by ˜45 mV which considerably enhances the reliability.

### Sub-Array Level Performance

To explore the hardware overhead of the architecture of the present disclosure on top of an standard unmodified SOT-MRAM platform, an iso-capacity performance comparison is performed. Both platforms are developed with a sample 32 Mb-single Bank, 512-bit Data Width in NVSim memory evaluation tool. The circuit level data is adopted from the circuit level simulation and then fed into an NVSim-compatible PIM library to report the results. The following table lists the performance measures for dynamic energy, latency, leakage power, and area. It is observed that there is a ˜30% increase in the area to support the proposed in-memory computing functions for genome assembly. As for dynamic energy, the architecture of the present disclosure shows an increase in R (Read) energy in spite of power gating mechanism used in the reconfigurable SA to turn off non-selected SAs (SA-I and -II while reading operation). In this way, C-Add (C stands for Computation) requires ˜2.4× more power compared with a single SA read operation. However, the following table demonstrates that the architecture of the present disclosure is able to offer a close-to-read latency for C-AND3 and C-Add compared with the standard design. There is also an increase in leakage power obviously coming from the add-on CMOS circuitry.

### Performance Comparison Between an Standard Sot-Mram Chip and Panda

| | area | dynamic energy (nJ) | | | | latency (ns) | | | | leak. power |
|---|---|---|---|---|---|---|---|---|---|---|
| Designs | (mm²) | R | W | C-AND3 | C-Add | R | W | C-AND3 | C-Add | (mW) |
| Standard | 7.06 | 0.57 | 0.66 | — | — | 3.85 | 4.5 | — | — | 402 |
| PANDA | 9.3 | 0.78 | 0.69 | 0.85 | 1.93 | 3.91 | 4.59 | 3.91 | 3.91 | 586 |

### Software Support

The architecture of the present disclosure is designed to be an efficient and independent accelerator for DNA assembly. However, it also needs to be exposed to programmers and system-level libraries to use it. The architecture of the present disclosure could be directly connected to the memory bus or through PCI-Express lanes as a third party accelerator. Thus, it could be integrated similar to that of GPUs. So, an ISA and a virtual machine for parallel and general-purpose thread execution need to be developed like NVIDIA's PTX. With that, at install time, the programs are translated to the architecture of the present disclosure's ISA discussed here to implement the in-memory functions listed in Table 1.

PANDA_Mem_insert (des, src, size) instruction is introduced to read a source data from the memory and write it back to a destination memory location consecutively. The size of input vectors for in-memory computation could be at most a multiple of the architecture of the present disclosure sub-array row size. PANDA_Cmp (src1, src2, size) performs parallel bulk bit-wise comparison operation between source vector 1 and 2. PANDA_Add (src1, src2, size) runs element-wise addition between cells located in a same column as will be explained subsequently.

### Algorithm and Mapping for the Architecture of the Present Disclosure

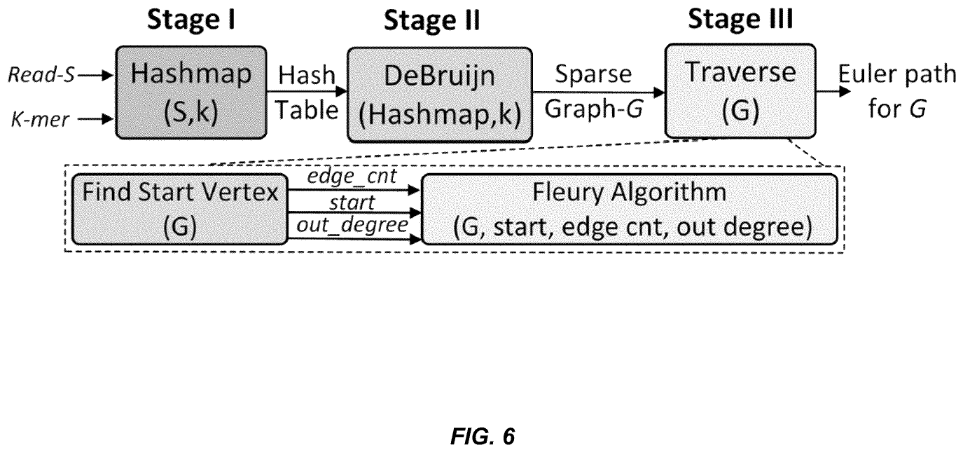

FIG. 6 illustrates an example of genome assembly stages according to some embodiments of the present disclosure. First, creating a hash table out of chopped short reads (k-mers) and keeping a count of each distinct k-mer; second, constructing a de Bruijn Graph with Hashmap; third, traversing through de Bruijn Graph for Euler Path. There is a final stage called scaffolding to close the gaps between contigs, which is the result of the denovo assembly.

The first three stages can take a large fraction of execute time and computational resources (over 80%) in both CPU and GPU implementations. To effectively handle the huge number of short reads, the assembly algorithm is modularized by focusing on parallelizing the main steps by loading only the necessary data at each stage into the architecture platform.

Stage One: Hash Table
Algorithm 1 Procedure Hashmap(S, k)

| | Step-1. Initialization: | |
|---|---|---|
| 1: | hashtable named Hashmap = { } | |
| | Step-2. Fill out the table: | |
| 2: | for i := 0 to length(S)-k+1 do | |
| 3: | k_mer ← S[i : i + k] | [symbol] copy values of S[i to i + k] into variable k_mer |

| 4: | if PANDA′Cmp(k_mer, Hashmap) == 0 then | |
|---|---|---|
| 5: | PANDA_Mem′insert(k_mer, 1) | |
| 6: | else | |
| 7: | New_frq ← PANDA_Add(k_mer, 1) | [symbol] increment frq by 1 |
| 8: | PANDA_Mem′insert(k_mer, New_frq) | [symbol] insert into Hashmap again |

| | |
|---|---|
| 9: | end if |
| 10: | end for |
| 11: | return Hashmap |

Algorithm 1, illustrated above, demonstrates that the reconstructed Hashmap(S,k) procedure in which the algorithm takes k-mer from the original sequence (S) in each iteration, creates a hash table entry (key) for that, and assigns its frequency (value) to 1.

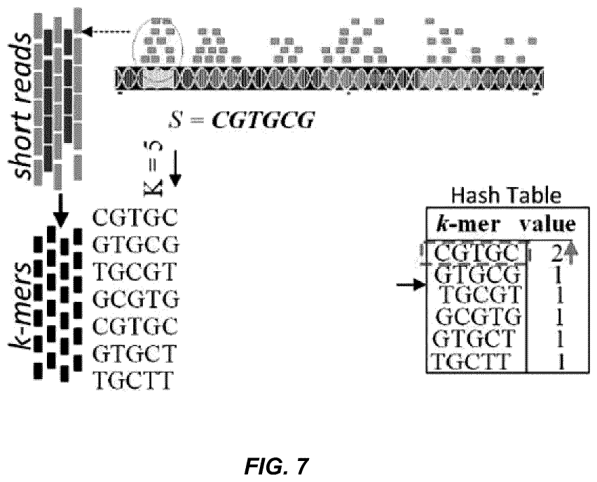

FIG. 7 illustrates an example of hash table generation from k-mers according to some embodiments of the present disclosure. If the k-mer is already in the table, it will calculate a new frequency (New_frq) by adding the previous frequency by one and update the value. As indicated, Hashmap procedure can be implemented through PANDA_Cmp (comparison), PANDA_Add (addition), and PANDA_Mem_insert (memory W/R) in-memory operations. Such functions are iteratively used in every step of ‘for’ loop and the architecture of the present disclosure is specially designed to handle such computation-intensive load through performing comparison, summing, and copying operations.

Considering that the number of different keys in Hash table is almost comparable to the genome size G, the memory space requirement to save the hash is given by ˜2×G×(k+1) bits (The factor of 2 is given to represent 2 bits per nucleotide). For instance, storing Hash table for human genome with G ˜3×10⁹ and k=32 requires ˜23 GB mostly associated with storing the key. Due to very large memory space requirement of hash table for assembly-in-memory algorithm, these tables are partitioned into multiple sub-arrays to fully leverage the architecture's parallelism, and to maximize computation throughput. Larger memory units and distributed memory schemes are generally preferable.

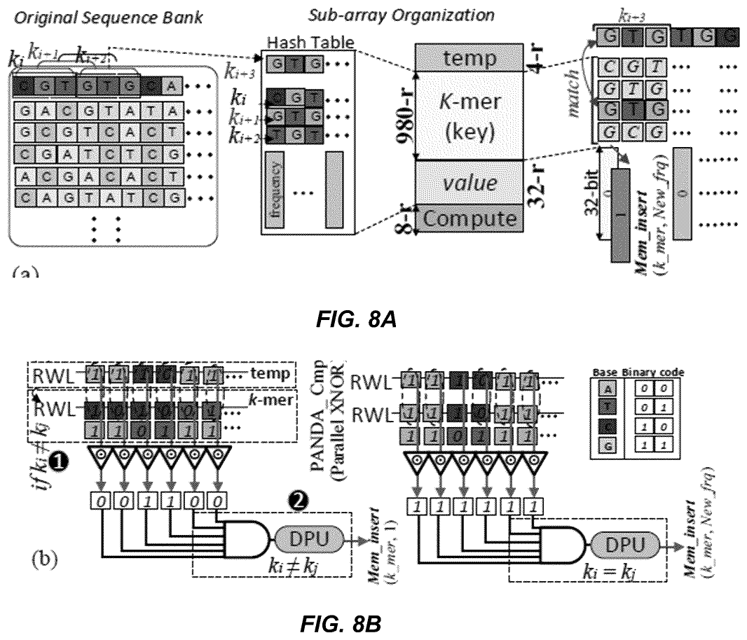

FIG. 8A illustrates an example of a proposed correlated data partitioning and mapping methodology for creating hash table(s). FIG. 8B illustrates an example of realization of parallel in-memory comparator (PANDA Cmp) between k-mers in a computational sub-array according to some embodiments of the present disclosure. The proposed correlated partitioning and mapping methodology, as shown in FIG. 8A, locally stores correlated regions of k-mer (980 rows) vectors, where each row stores up to 128 bps (A, C, G, T encoded by 2 bits) and value (32 rows) vectors in the same sub-array. For counting the frequencies of each distinct k-mer, the ctrl first reads and parses the short reads from the original sequence bank to the specific sub-array. As depicted in of FIG. 8A, assuming S=CGTGTGCA as the short read, the k-mers-kᵢ-kᵢ₊ₙ are extracted and written into the consecutive memory rows of k-mer region. However, when a new query such as kᵢ₊₃ arrives (while kᵢ-kᵢ₊₂ are already in the memory), it will be first written to the temp region. A parallel in-memory comparison operation (PANDA_Cmp) will be performed between temp data and already-stored k-mers. FIG. 8B intuitively shows PANDA_Cmp procedure, where entire temp row can be compared with a previous k-mer row in a single cycle. Then, a built-in ctrl's AND unit in DPU readily takes all the results to determine the next memory operation according to the algorithm. To increase the frequency of a specific k-mer, PANDA_Add is leveraged to perform in-memory addition without sending data to off-chip processor

### Stage 2: Graph Construction

The next step is to construct and access a de Bruijn graph based on the Hash structure to rapidly lookup of a “value” associated with each k-mer. For each entry (of length k) in the Hashmap, two nodes are made: one with the prefix of length k−1 and other with the suffix of length k−1 (e.g. CGTGC→CGTG and GTGC), and an edge is connected between them.

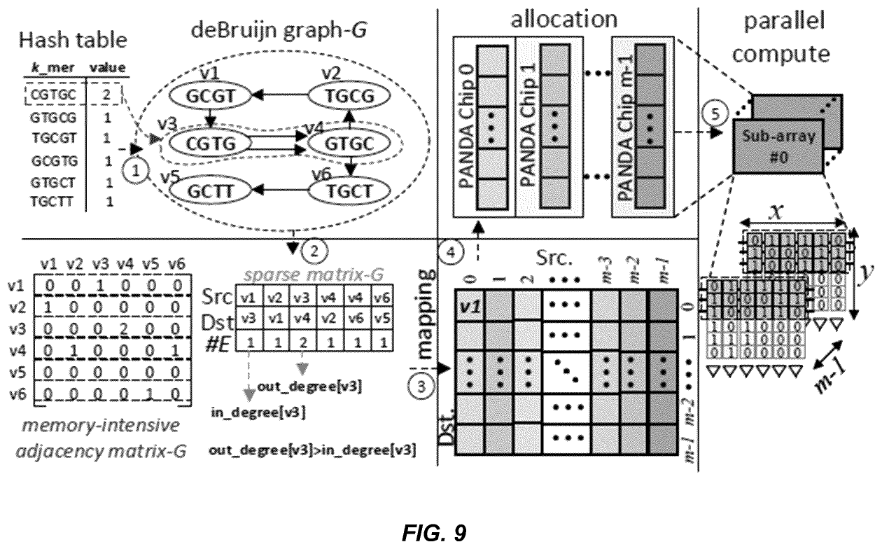

FIG. 9 illustrates an example of graph construction with sparse matrix with partitioning, allocation, and parallel computation according to some embodiments of the present disclosure. For each Hash table entry with n as the frequency, n edges is then added between the two nodes. The de Bruijn graph G for the example Hash table illustrated in FIG. 7 is constructed in step 1 of FIG. 9. Algorithm 2, produced below, shows the reconstructed de Bruijn procedure for PANDA taking Hashmap data and k as input returning matrix G.

Algorithm 2 Procedure DeBruijn(Hashmap, k)

| | Step-1. Initialization: |
|---|---|
| 1: | G=[ ], Nodes_List=[ ], i=1 |
| | Step-2. Sparse Graph Construction: |
| 2: | for ∀k_mer ∈ Hashmap.keys( ), i + + do |
| 3: | node_1 ← k_mer[0 : k − 2] |
| 4: | node_2 ← k_mer[1 : k − 1] |
| 5: | PANDA_Mem′insert(G[1][i], node_1) |
| 6: | PANDA_Mem′insert(G[2][i], node_2) |
| 7: | PANDA_Mem′insert(G[3][i], Hashmap[k_mer]) |
| 8: | end for |
| 9: | return G |

For each key within Hash table, PANDA_Mem_insert_instruction creates an entry in G for node1 and node2s. Leveraging adjacency matrix representation for direct mapping of such humongous sparse graph into memory comes at a cost of significantly increased memory requirement and run time. The size of adjacency matrix will be V×V for any graph with V nodes, where sparse matrix could be represented by a 3×E matrix, where E is the total number of edges in the graph. The architecture of the present disclosure utilizes sparse matrix representation, as illustrated in step 2 of FIG. 9, for mapping purpose. Each entry in the 3^{rd} row of the sparse matrix represents the number of connections between two nodes in 1^{st} and 2^{nd} rows

To balance workloads of each chip of the present disclosure, and to maximize parallelism, an interval-block partitioning method is utilized. A hash-based approach is used by splitting the vertices into M intervals and then divide edges into M² blocks as illustrated in step 3 of FIG. 9. Then each block is allocated to a chip, as illustrated in step 4 of FIG. 9, and mapped to its sub-arrays. Having an m-vertex sub-graph with Nₛ activated sub-arrays (size=x×y), each sub-array can process n vertices (n≤f|n∈N, f=min(x, y)) (step 5: parallel computation). In this way, the number of processing sub-arrays for an N-vertex sub-graph can be formulated as

$${N}_{s} = ⌈ \frac{N}{f} ⌉ .$$

After graph construction, it is possible to perform a round of simplification on the sparse graph stored in PANDA without loss of information to avoid fragmentation of the graph. As a matter of fact, the blocks are broken up each time a short read starts or ends leading to linear connected subgraphs. This fragmentation imposes longer execution time and larger memory space. The simplification process easily merges two nodes within memory if a node-A has only one out-going edge directed to node-B with only one in-going edge.

### Stage Four: Traversal for Euler Path

The input of this stage will be a sparse representation of graph G. For traversing all the edges, Fleury's algorithm can be utilized to find the Euler path of that graph (a path which traverses all edges of a graph). Basically, a directed graph has a Euler path if the in_degree and out_degree¹ of every vertex is same or, there are exactly two vertices which have |in_degree−out_degree|=1. Finding the starting vertex is very important to generate the Eulerian path and any vertex cannot be considered as a starting vertex. The reconstructed PIM-friendly algorithm for finding the start vertex in graph-G in shown in algorithm 3, produced below

Algorithm 3 Procedure Find Start Vertex(G)

| | Step-1. Initialization: | |
|---|---|---|
| 1: | start ← 0, end ← 0 | |
| 2: | edge_cnt ←0 | [symbol] For counting number of edges in G |
| 3: | Len ← size(G) | |
| | Step-2. Find the start vertex: | |
| 4: | for n in Nodes do | |
| 5: | in_degree[i] ← 0 | |
| 6: | out_degree[i] ← 0 | |
| 7: | end for | |
| 8: | for n in Nodes do | |
| 9: | for k := 1 to Len do | |
| 10: | If PANDA′Cmp(G[1][k], n) then | [symbol] node n has an out-going edge |

| | |
|---|---|
| 11: | out_degree[n] ← PANDA_Add(out_degree[n], int(G[3][k])) |
| 12: | in_degree[int(G[2][k])] ← PANDA_Add(in_degree[int(G[2][k])], int(G[3][k]) |
| 13: | edge_cnt ← PANDA_Add(edge_cnt, int(G[3][k])) |
| 14: | end if |
| | end for |
| 16: | if PANDA′Cmp(out_degree[n], in_degree[n] + 1) then |
| 17: | start ← n |
| 18: | else |
| 19: | start ← first_node |
| 20: | end if |
| 21: | end for |
| 22: | return start & edge_cnt & out_degree |

For each node, this stage deals with massive number of iteratively-used PANDA_Add to calculate the number of in_degree, out_degree and edge_cnt (total number of edges). Moreover, in order to check the condition (|out_degree=in_degree|+1), parallel PANDA_Cmp operation is required.

After finding the start node, PANDA has to traverse through the length of sparse matrix G from the starting vertex and check two conditions for each edge and accordingly add qualified edges to the Eulerian Path. The reconstructed Fleury algorithm is demonstrated in Algorithm 4, produced below.

Algorithm 4 Procedure Fleury(G, node, edge_count, out_degree)

| 1: | for v = 0 to N do | |
|---|---|---|
| 2: | if G[1][k] == start then | |
| 3: | v ← G[2][k] | |
| 4: | if isValidNextEdge(v) then | |
| 5: | PANDA_Mem′insert(v) | [symbol] add (start, v) in the Eulerian path |
| 6: | PANDA_Add(out_degree[start], −1) | |
| 7: | PANDA_Add(G[3][k], −1) | [symbol] remove one edge from the graph |
| 8: | PANDA_Add(edge_cnt, −1) | |
| 9: | end if | |
| 10: | end if | |
| 11: | Fleury(G, v, edge_count, out_degree[ ]) | [symbol] run Fleury again for the next node v |

| | |
|---|---|
| 12: | end for |

If an edge is not a bridge and is not the last edge of the graph, (start, v) can be added in the Eulerian path and that edge can be removed. isValidNextEdge( ) function will check if the edge (u, v) is valid to be included into the Euler path. If v is the only adjacent vertex remaining for u, it means that, all other adjacent vertices have been traversed, so this edge will be taken, otherwise it won't. The second condition counts the number of reachable nodes from u before and after removing the edge. If the number changes/decreases, it means that, the edge was a bridge (removing it will disconnect the graph into two parts). If it is a bridge, the edge cannot be removed from the Graph; otherwise the edge will be removed from the graph and added into Euler path.

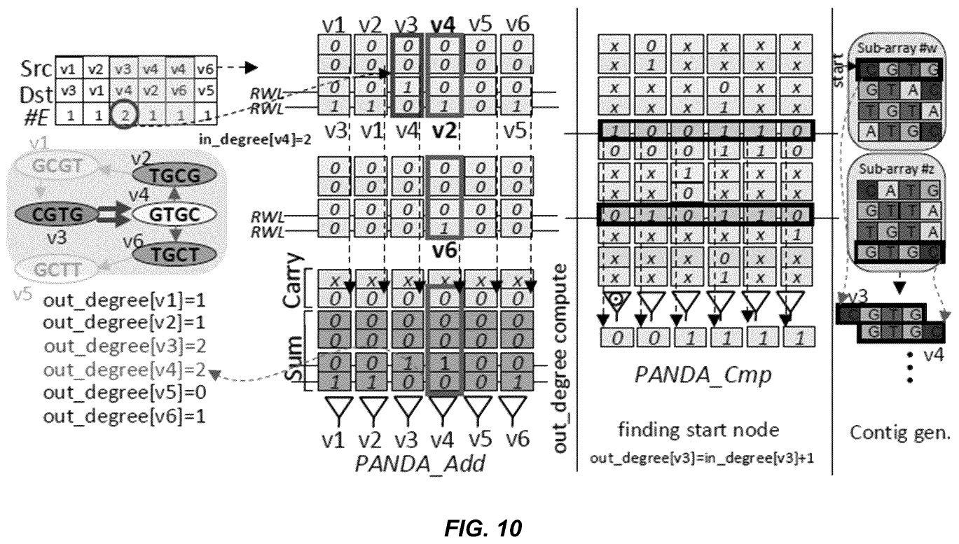

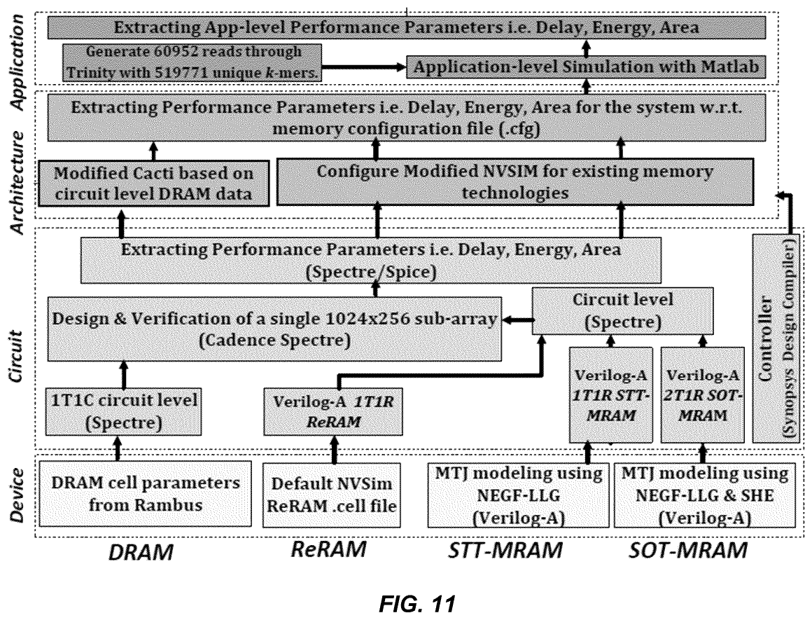

FIG. 10 illustrates an example of in-memory addition and comparison scheme for finding the start vertex according to some embodiments of the present disclosure. In the interest of space, _/in_degree and edge_cnt mapping and computation are shown in the platform of the present disclosure in FIG. 10, which basically sums up all the entries of a particular node i of valid links connected to a vertex to find the start vertex. As can be seen, the sparse matrix representation is used to store the matrix-G. In the mapping technique, each column is assigned to a distinct source vertex in the graph and then filled out with the number of edges (#E) only linked to existing destination vertices in a vertical fashion. Therefore, destination vertices are not assigned to the memory rows as in direct adjacency matrix mapping.

Here, a 4-bit representation is considered for the simplicity. For example, v4 has out-going edges to v2 and v6 that are stored vertically in a sub-array. The architecture of the present disclosure could perform parallel in-memory addition to calculate the total number of out_degree for all nodes in parallel. For this task, two rows in the sub-array are initialized to zero as Carry reserved rows such that they can be selected along with two operands (here v4→v2 data (0001) and v4→v6 data (0001)) to perform parallel in-memory addition. To perform parallel addition operation and generate initial Carry and Sum bits, the architecture of the present disclosure takes every three rows to perform a parallel in-memory addition. The results are written back to the memory reserved space (Resv.). Then, next step only deals with multi-bit addition of resultant data starting bit-by-bit from the LSBs of the two words continuing towards MSBs. Then the architecture of the present disclosure is able to perform comparison between number of out_degree and in_degree for each node in parallel to determine the start node. After finding the start node, as demonstrated in FIG. 10, contig. generation can be readily accomplished through finding the Eulerian path and putting together each vertex data from different sub-arrays.

### Performance Estimation

### Setup

### Accelerator

As this disclosure is the first to explore the performance of a PIM platform for genome assembly problem, an evaluation test bed must be created from scratch to have an impartial comparison with both von-Neumann and non-von-Neumann architectures. The architecture of the present disclosure's computational memory sub-array is configured with 1024 rows and 256 columns, 4×4 memory matrix (with 1/1 as row/column activation) per bank organized in H-tree routing manner, 16×16 banks (with 1/1 as row/column activation) in each memory chip. For comparison, five computing platforms are considered: 1) A general purpose processor (GPP): a Quad Core Intel® Core i7-7700 CPU @ 3.60 GHz processor with 8192 MB DIMM DDR4 1600 MHz RAM and 8192 KB Cache; 2) A processing-in-STT-MRAM platform capable of performing bulk bit-wise operations; 3) A recently developed processing-in-SOT-MRAM platform for DNA sequence alignment optimized to perform comparison-intensive operations; 4) A processing-in-ReRAM accelerator designed for accelerating bulk bit-wise operations; 5) A processing-in-DRAM accelerator based on Ambit working with triple row activation mechanism to implement various functions.

FIG. 11 illustrates an example of an evaluation framework developed for processing-in-memory platforms according to some embodiments of the present disclosure. The detailed evaluation framework developed for PIM platforms is illustrated in FIG. 11. All PIM platforms have an identical physical memory configuration as the architecture of the present disclosure. Additionally, a similar cross-layer simulation framework is developed starting from device-level simulation all the way to circuit- and architectural level as explained for the architecture of the present disclosure previously. The results of the architecture evaluation of all PIM platforms were then fed to a high-level in-house simulator developed in Matlab to perform each genome assembly stage based on the customized and PIM-friendly algorithm and estimate the overall performance. It is noteworthy that DPU was developed in HDL and the performance results was extracted with synopsys design compiler and fed to the developed NVSim library for each PIM platform.

To evaluate the CPU performance, Trinity-v2.8.5 is utilized, which was shown to be sensitive and efficient in recovering full-length transcripts. Trinity constructs de Bruijn graph from short-read sequences and employs an enumeration algorithm to score all branches, and keeps possible ones as isoforms/transcripts.

### Experiment

In the experiment, 60952 short reads are created through Trinity sample genome bank with 519771 unique k-mers. Initially, the k-mer length, k, is set to default 25, and then changed to 22, 27, and 32 as typical values for most genome assemblers. To clarify, the CPU executes the Inchworm, Chrysalis, and Butterfly steps in Trinity, while PIM platforms run three main procedures in genome assembly shown in FIG. 6 i.e. Hashmap, DeBruijn, and Traverse for under-test PIM platforms. Trinity's power consumption and execution time is compared to that of other PIM assemblers by several measures. To have a fair comparison with such a comprehensive assembler (that performs full genome assembly task with scaffolding step), the PIM platforms are penalized with ˜25% excessive time and power. Generally, it is believed that this could provide a more realistic comparison with a von-Neumann architecture-based assembler.

### Run Time

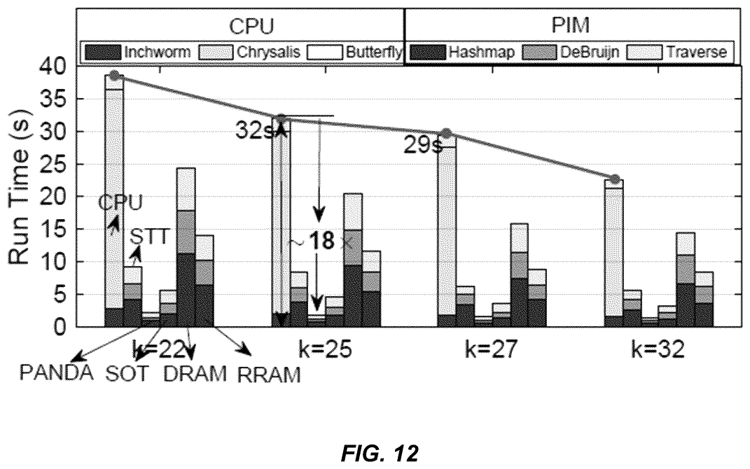

FIG. 12 illustrates an example of a breakdown of run time for under-test platforms running different k-mer-length genome assembly task according to some embodiments of the present disclosure. The execution time of genome assembly task for different platforms is reported in FIG. 12. For k=25, the CPU platform executes the Inchworm, Chrysalis, and Butterfly steps of Trinity in ˜32 s, where Chrysalis for clustering the contigs and constructing complete de Bruijn graph takes the largest fraction of the run time (28 s) as expected. However, the comparison operation-intensive Hashmap procedure for k-mer analysis takes the largest fraction of execution time in all PIM platforms (over 40% of total run time). Larger k-mer length typically diminishes the de Bruijn graph connectivity by simultaneously reducing the number of ambiguous repeats in the graph and chance of overlap between two reads. That is why run time for all platforms reduces with increase of k-mer length.

It can be observed that PIM platforms reduce the run time remarkably compared to the CPU. As shown, the architecture of the present disclosure reduces the run time by ˜18× compared to the CPU platform for k=25 (18.8× on average over 4 different k-mer lengths). The architecture of the present disclosure essentially accelerates the graph construction and traversal stages by ˜21.5× compared with CPU platform. Now, by increasing the k-length to 32, the higher speed-up is even achievable. Compared with counterpart PIM platforms, the X(N)OR-friendly design reduces the run time on average by 4.2×, 2.5×, compared to STT-PIM, and SOT-PIM platforms as the fastest counterparts, respectively. This comes from the fact that under-test PIM platforms require multi-cycle operations to implement addition operation. The SOT-based device intrinsically shows higher write speed compared to STT devices. Compared to DRAM and RRAM platforms, the architecture of the present disclosure achieves on average 10.9× and 6× speed-up for various length k-mer processing. It should be noted that the processing-in-DRAM platforms possess a destructive computing operation and require multiple memory cycle to copy the operands to particular rows before computation. As for Ambit, 7 memory cycles are needed to implement in-memory-X(N)OR function.

### Power Consumption

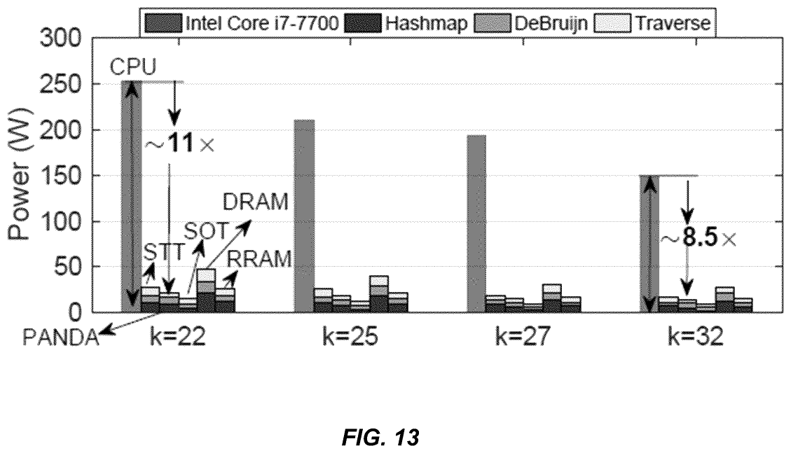

FIG. 13 illustrates estimations of the power consumption of different PIM platforms for running different length k-mers compared to the CPU platform. Based on the results, a significant reduction in power consumption can be reported for all under-test PIM platforms compared with the CPU. The breakdown of energy consumption is also shown for the PIM platforms, however this couldn't be accurately achieved for the CPU and overall power consumption is reported. In the experiment, processing-in-SOT-MRAM design achieves the smallest power consumption (on average) to run the three main procedures, as compared with the CPU and other PIM platforms. The platform of the architecture of the present disclosure stands as the second most power-efficient design. This is mainly due to the three-SA based bit-line computing scheme in the architecture of the present disclosure, compared with two-SA per bit-line technique in the counterpart design.

While the proposed scheme brings more speed-up compared with the design in, it requires relatively more power. The architecture of the present disclosure reduces the power consumption by ˜9.2× on average compared with the CPU platform over different length k-mers. Additionally, the architecture can reduce the power consumption by ˜18% compared with an STT-MRAM platform. The main reason behind this improvement is more efficient addition operation in the architecture of the present disclosure. Addition operation requires additional memory cycles in the STT-MRAM platform to save carry bit back to the memory and use it again for the computation of next bits. Compared to DRAM and RRAM platforms, the architecture of the present disclosure obtains on average 2.11× and 55% power reduction for various length k-mer processing

### Speed-Up/Power-Efficiency Trade-Off

The power-efficiency and speed-up of three best under-test PIM platforms can be investigated based on the run time and power consumption results in the previous subsections, by tuning the number of active sub-arrays (Nₛ) associated with the comparison and addition operations. A parallelism degree (P_{d}) can be then defined as the number of replicated sub-arrays to boost the performance of the PIM platforms through parallel processing as shown in prior works. For example, when P_{d} is set to 2, two parallel sub-arrays are undertaken to process the in-memory operations, simultaneously. It is expected that such parallelism will improve the performance of genome assembly at the cost of sacrificing the power consumption and area.

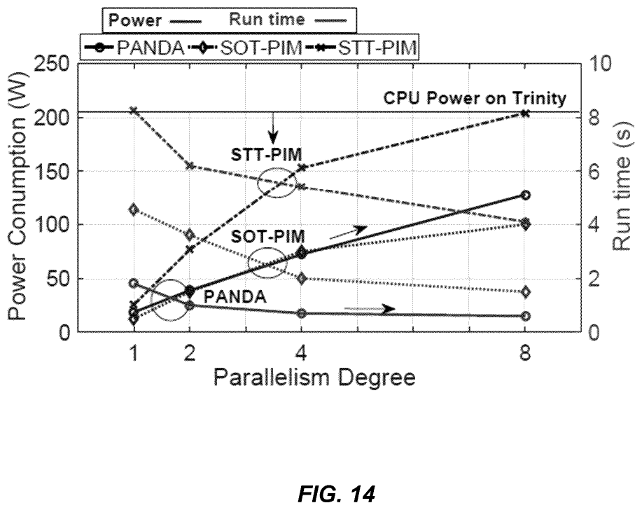

FIG. 14 plots the existing trade-off between run time and power consumption vs. P_{d} for k=25. The estimated CPU power budget required to execute Trinity is also shown. It can be seen that for all platforms the run time reduces by increasing the parallelism. For example for PANDA platform in an extreme case, increasing P_{d} from 1 to 8 increases the power consumption from ˜19 W to 128 W (˜7×) and reduces the execution time by a factor of 3, which might not be a favorable case. Therefore, a user can meticulously tailor the performance of the architecture of the present disclosure to meet the system/application constraints. Here, the optimum theoretical performance of the architecture of the present disclosure and other PIM platforms is demonstrated by pinpointing the intersection between power and run time curves illustrated in FIG. 14. It is observed that the architecture of the present disclosure achieves the smallest run time and power consumption task with a P_{d}˜2 compared with the others.

### Memory Wall Challenge

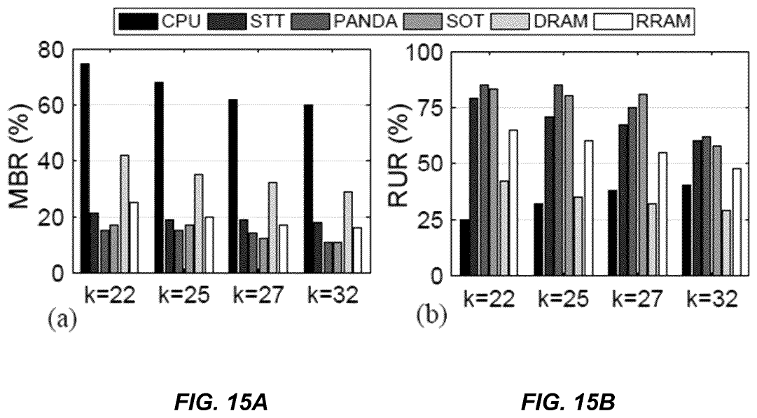

FIG. 15A illustrates an example of the memory bottleneck ratio according to some embodiments of the present disclosure. FIG. 15B illustrates an example of resource utilization ratio for CPU and three under-test PIM platforms for running genome assembly task according to some embodiments of the present disclosure. The power-efficiency and speed-up of PIM platforms against the von-Neumann architecture-based CPU is discussed previously. Here, the reasons behind the numbers reported are further explored by considering two new measures i.e. Memory Bottleneck Ratio (MBR) and Resource Utilization Ratio (RUR). MBR is defined as the time fraction needed for data transfer from/to on-chip or off-chip, when computation has to wait for data i.e. memory wall happens. RUR is defined as the time fraction in which the computation resources are loaded with data. The memory wall is considered as the main bottleneck that brings large power consumption and lengthen execution time in CPU. The MBR is illustrated in (a) of FIG. 15. The peak throughput for each design in four distinct k-mer lengths is taken into account for performing the evaluation.

This evaluation mainly considers the number of memory access. As shown, the architecture of the present disclosure uses less than ˜17% time for data transfer due to the PIM acceleration schemes, while CPU's MBR increases to 65% when k=25. It is observed that all the other PIM platforms except DRAM also spend less than ˜17% time for data communication. The smaller MBR can be translated as the higher RUR for the accelerators, as illustrated in FIG. 15. The less MBR can be understood as a higher RUR. It is demonstrated that with up to ˜82%, PANDA achieves the highest RUR. Taking everything into account, PIM acceleration schemes offer a high utilization ratio (>60% excluding DRAM) confirming the conclusion illustrated in FIG. 15A. The memory wall evaluation shows the efficiency of the architecture of the present disclosure for solving the memory wall challenge.

Accordingly, the architecture of the present disclosure is presented as a new processing-in-SOT-MRAM platform to accelerate processing operations. As a specific example, the comparison/addition-extensive genome assembly application can be accelerated using PIM-friendly operations. However, it should be noted that genomics examples are utilized throughout the present disclosure merely to illustrate one example utilization of the architecture, and that the architecture is certainly not limited to such use-cases. Rather, systems and methods of the present disclosure can be applied broadly to any use-case in which processing operations are utilized.

The architecture of the present disclosure is developed based on a set of new circuit-level schemes to realize a data-parallel computational core for genome assembly. The platform is configured with a novel data partitioning and mapping technique that provides local storage and processing to fully utilize the customized algorithm-level's parallelism. The cross-layer simulation results included herein demonstrate that systems and methods of the present disclosure produce a number of technical effects and benefits. Specifically, systems and methods of the present disclosure reduce the execution time and power utilization respectively by ˜18× and ˜11× compared with the CPU. Speed-ups of up-to 2-4× can be obtained over recent processing-in-MRAM platforms to perform the similar task. As such, systems and methods of the present disclosure provably reduce power utilization, and increase processing speed, to a significant degree, therefore optimizing processing operations and significantly reducing utilization of resources (e.g., processing cycles, power, hardware resources, etc.).

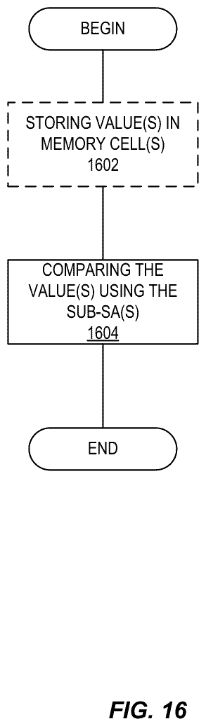

FIG. 16 is a flowchart for a method for efficient in-memory processing of complete Boolean logic operations according to some embodiments of the present disclosure. Note that according to some embodiments, one or more steps in FIG. 16 can be performed, while other steps are optional. Such steps are indicated by a dashed box.

At step 1602, a memory device stores value(s) in memory cell(s). More specifically, the memory device stores one or more values in one or more non-volatile memory cells of a plurality of non-volatile memory cells of a memory subarray of the non-volatile memory device. The memory subarray includes the plurality of non-volatile memory cells, a modified row decoder, a sense amplifier (SA) comprising a plurality of sub-SAs, wherein the plurality of sub-SAs are respectively associated with a plurality of functions, and a plurality of reference resistors.

At step 1604, the memory device compares the value(s) using the sub-SA(s). More specifically, the memory device compares, using one or more of the plurality of sub-SAs of the memory subarray, the one or more values of with one or more of the plurality of reference resistors to obtain a processing output.

In some embodiments, the plurality of functions comprise one or more of a read function, a NOR function, a OR function, a AND function, a NAND function; a XOR function, a XNOR function, a MAJ function, a MIN function, a READ function, or a SUM function.

In some embodiments, the memory bank comprises a control unit configured to select the one or more of the plurality of reference resistors using a plurality of control bits.

In some embodiments, the memory bank comprises one or more Read Word Lines (RWLs). In some embodiments, prior to comparing the one or more values, the memory subarray is configured to simultaneously activate, with the modified row decoder, at least one of the one or more RWLs to obtain the one or more values of the one or more non-volatile memory cells.

In some embodiments, a first sub-SA of the one or more sub-SAs is associated with a 3-input OR function, a second sub-SA of the one or more sub-SAs is associated with a 3-input AND function, a third sub-SA of the one or more sub-SAs is associated with a 3-input MAJORITY function, and the processing output comprises an addition output or a subtraction output.

In some embodiments, the processing output comprises a SUM output and a CARRY output, the third sub-SA is configured to generate the carry output, the first sub-SA is configured to generate the SUM output when the CARRY output is 0, and the second sub-SA is configured to generate the SUM output when the CARRY output is 1.

In some embodiments, each of a subset of memory cells from the plurality of non-volatile memory cells comprises a value of 1, and the one or more values comprise three values for three respective memory cells, wherein one of the three respective memory cells is a memory cell from the subset of memory cells.

In some embodiments, a sub-SA of the one or more sub-SAs is associated with a two-input XNOR function and/or a three-input XOR function.

In some embodiments, the memory subarray is configured to compare the one or more values within a single memory cycle of the memory bank.

In some embodiments, the plurality of non-volatile memory cells comprises a plurality of Magnetic Random Access Memory (MRAM) cells.

In some embodiments, the memory device comprises a Spin-Orbit Torque Magnetic Random Access Memory (SOT-MRAM) device.

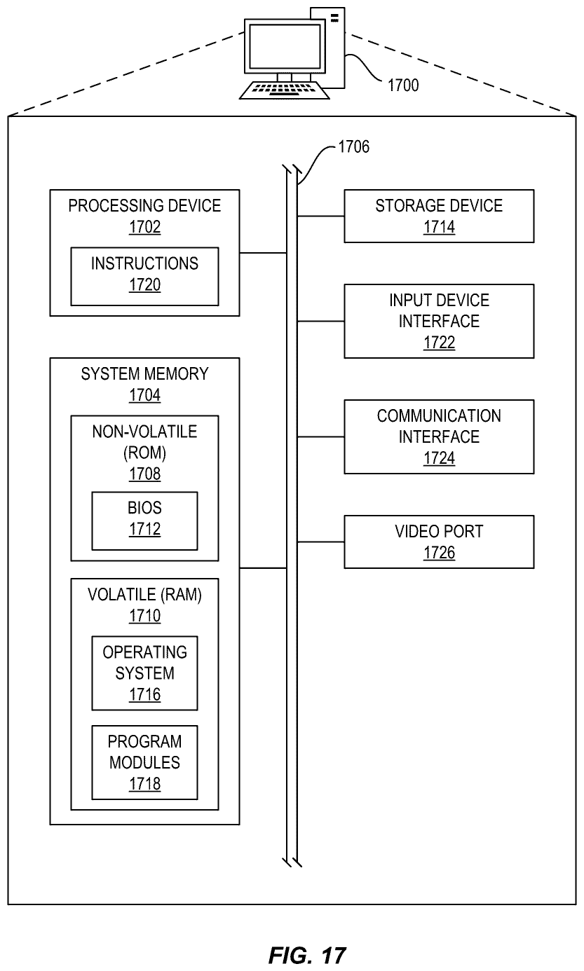

FIG. 17 is a block diagram of a computing system including a memory device suitable for implementing efficient in-memory processing according to some embodiments of the present disclosure. The computing system includes or is implemented as a computer system 1700, which comprises any computing or electronic device capable of including firmware, hardware, and/or executing software instructions that could be used to perform any of the methods or functions described above, such as efficient in-memory processing. In this regard, the computer system 1700 may be a circuit or circuits included in an electronic board card, such as a printed circuit board (PCB), a server, a personal computer, a desktop computer, a laptop computer, an array of computers, a personal digital assistant (PDA), a computing pad, a mobile device, or any other device, and may represent, for example, a server or a user's computer.

The exemplary computer system 1700 in this embodiment includes a processing device 1702 or processor, a system memory 1704, and a system bus 1706. The system memory 1704 may include non-volatile memory 1708 and volatile memory 1710. The non-volatile memory 1708 may include read-only memory (ROM), erasable programmable read-only memory (EPROM), electrically erasable programmable read-only memory (EEPROM), and the like.

Specifically, the non-volatile memory 1708 includes the modified memory device(s) of the present disclosure. For example, the non-volatile memory 1708 includes the memory device described with regards to FIGS. 2, 3, and/or 4.

The volatile memory 1710 generally includes random-access memory (RAM) (e.g., dynamic random access memory (DRAM), such as synchronous DRAM (SDRAM)). A basic input/output system (BIOS) 1712 may be stored in the non-volatile memory 1708 and can include the basic routines that help to transfer information between elements within the computer system 1700.

The system bus 1706 provides an interface for system components including, but not limited to, the system memory 1704 and the processing device 1702. The system bus 1706 may be any of several types of bus structures that may further interconnect to a memory bus (with or without a memory controller), a peripheral bus, and/or a local bus using any of a variety of commercially available bus architectures.

The processing device 1702 represents one or more commercially available or proprietary general-purpose processing devices, such as a microprocessor, central processing unit (CPU), or the like. More particularly, the processing device 1702 may be a complex instruction set computing (CISC) microprocessor, a reduced instruction set computing (RISC) microprocessor, a very long instruction word (VLIW) microprocessor, a processor implementing other instruction sets, or other processors implementing a combination of instruction sets. The processing device 1702 is configured to execute processing logic instructions for performing the operations and steps discussed herein.

In this regard, the various illustrative logical blocks, modules, and circuits described in connection with the embodiments disclosed herein may be implemented or performed with the processing device 1702, which may be a microprocessor, field programmable gate array (FPGA), a digital signal processor (DSP), an application-specific integrated circuit (ASIC), or other programmable logic device, a discrete gate or transistor logic, discrete hardware components, or any combination thereof designed to perform the functions described herein. Furthermore, the processing device 1702 may be a microprocessor, or may be any conventional processor, controller, microcontroller, or state machine. The processing device 1702 may also be implemented as a combination of computing devices (e.g., a combination of a DSP and a microprocessor, a plurality of microprocessors, one or more microprocessors in conjunction with a DSP core, or any other such configuration).

The computer system 1700 may further include or be coupled to a non-transitory computer-readable storage medium, such as a storage device 1714, which may represent an internal or external hard disk drive (HDD), flash memory, or the like. The storage device 1714 and other drives associated with computer-readable media and computer-usable media may provide non-volatile storage of data, data structures, computer-executable instructions, and the like. Although the description of computer-readable media above refers to an HDD, it should be appreciated that other types of media that are readable by a computer, such as optical disks, magnetic cassettes, flash memory cards, cartridges, and the like, may also be used in the operating environment, and, further, that any such media may contain computer-executable instructions for performing novel methods of the disclosed embodiments.

An operating system 1716 and any number of program modules 1718 or other applications can be stored in the volatile memory 1710, wherein the program modules 1718 represent a wide array of computer-executable instructions corresponding to programs, applications, functions, and the like that may implement the functionality described herein in whole or in part, such as through instructions 1720 on the processing device 1702. The program modules 1718 may also reside on the storage mechanism provided by the storage device 1714. As such, all or a portion of the functionality described herein may be implemented as a computer program product stored on a transitory or non-transitory computer-usable or computer-readable storage medium, such as the storage device 1714, volatile memory 1710, non-volatile memory 1708, instructions 1720, and the like. The computer program product includes complex programming instructions, such as complex computer-readable program code, to cause the processing device 1702 to carry out the steps necessary to implement the functions described herein.

An operator, such as the user, may also be able to enter one or more configuration commands to the computer system 1700 through a keyboard, a pointing device such as a mouse, or a touch-sensitive surface, such as the display device, via an input device interface 1722 or remotely through a web interface, terminal program, or the like via a communication interface 1724. The communication interface 1724 may be wired or wireless and facilitate communications with any number of devices via a communications network in a direct or indirect fashion. An output device, such as a display device, can be coupled to the system bus 1706 and driven by a video port 1726. Additional inputs and outputs to the computer system 1700 may be provided through the system bus 1706 as appropriate to implement embodiments described herein.

The operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A non-volatile memory device for efficient in-memory processing of complete Boolean logic operations, comprising:
a memory bank comprising a plurality of memory subarrays, wherein each memory subarray comprises:
a plurality of non-volatile memory cells storing a respective plurality of values;
a modified row decoder;
a Sense Amplifier (SA) comprising a plurality of sub-SAs, wherein the plurality of sub-SAs are respectively associated with a plurality of functions; and
a plurality of reference resistors; and
wherein a memory subarray of the plurality of memory subarrays is configured to:
compare, with one or more of the plurality of sub-SAs, one or more values of one or more respective non-volatile memory cells of the plurality of non-volatile memory cells with one or more of the plurality of reference resistors to obtain a processing output.

2. The non-volatile memory device of claim 1, wherein the plurality of functions comprise one or more of:
a read function;
a NOR function;
a OR function;
a AND function;
a NAND function;
a XOR function;
a XNOR function;
a MAJ function;
a MIN function;
a READ function; or
a SUM function.

3. The non-volatile memory device of claim 1, wherein:
the memory bank comprises a control unit configured to select the one or more of the plurality of reference resistors using a plurality of control bits.

4. The non-volatile memory device of claim 1, wherein:
the memory bank comprises one or more Read Word Lines (RWLs); and
wherein, prior to comparing the one or more values, the memory subarray is configured to:
simultaneously activate, with the modified row decoder, at least one of the one or more RWLs to obtain the one or more values of the one or more non-volatile memory cells.

5. The non-volatile memory device of claim 4, wherein the memory subarray is further configured to:
in response to activating at least one of the one or more RWLS, receive one or more sense voltages at one or more of the plurality of sub-SAs; and
compare the one or more sense voltages to one or more reference voltages associated with the plurality of reference resistors.

6. The non-volatile memory device of claim 1, wherein:
a first sub-SA of the one or more sub-SAs is associated with a 3-input OR function;
a second sub-SA of the one or more sub-SAs is associated with a 3-input AND function;
a third sub-SA of the one or more sub-SAs is associated with a 3-input MAJORITY function; and
the processing output comprises an addition output or a subtraction output.

7. The non-volatile memory device of claim 6, wherein:
the processing output comprises a SUM output and a CARRY output;
the third sub-SA is configured to generate the carry output;
the first sub-SA is configured to generate the SUM output when the CARRY output is 0; and
the second sub-SA is configured to generate the SUM output when the CARRY output is 1.

8. The non-volatile memory device of claim 6, wherein:
each of a subset of memory cells from the plurality of non-volatile memory cells comprises a value of 1; and
the one or more values comprise three values for three respective memory cells, wherein one of the three respective memory cells is a memory cell from the subset of memory cells.

9. The non-volatile memory device of claim 8, wherein a sub-SA of the one or more sub-SAs is associated with a two-input XNOR function and/or a three-input XOR function.

10. The non-volatile memory device of claim 1, wherein the memory subarray is configured to compare the one or more values within a single memory cycle of the memory bank.

11. The non-volatile memory device of claim 1, wherein the plurality of non-volatile memory cells comprises a plurality of Magnetic Random Access Memory (MRAM) cells.

12. The non-volatile memory device of claim 1, wherein the memory device comprises a Spin-Orbit Torque Magnetic Random Access Memory (SOT-MRAM) device.

13. A method for efficient in-memory processing of complete Boolean logic operations, comprising:
storing one or more values in one or more non-volatile memory cells of a plurality of non-volatile memory cells of a memory subarray of a non-volatile memory device, wherein the memory subarray comprises:
the plurality of non-volatile memory cells;
a modified row decoder;
a Sense Amplifier (SA) comprising a plurality of sub-SAs, wherein the plurality of sub-SAs are respectively associated with a plurality of functions; and
a plurality of reference resistors; and
comparing, using one or more of the plurality of sub-SAs of the memory subarray, the one or more values of with one or more of the plurality of reference resistors to obtain a processing output.

14. The method of claim 13, wherein the plurality of functions comprise one or more of:
a read function;
a NOR function;
a OR function;
a AND function;
a NAND function;
a XOR function;
a XNOR function;
a MAJ function;
a MIN function;
a READ function; or
a SUM function.

15. The method of claim 13, wherein:
the non-volatile memory device comprises one or more Read Word Lines (RWLs); and
wherein, prior to comparing the one or more values, the method comprises:
simultaneously activating, using the modified row decoder of the memory subarray, at least one of the one or more RWLs of the non-volatile memory device to obtain the one or more values of the one or more non-volatile memory cells.

16. The method of claim 15, further comprising:
in response to activating at least one of the one or more RWLS, receiving one or more sense voltages at one or more of the plurality of sub-SAs; and
comparing the one or more sense voltages to one or more reference voltages associated with the plurality of reference resistors.

17. The method of claim 13, wherein:
a first sub-SA of the one or more sub-SAs is associated with a 3-input OR function;
a second sub-SA of the one or more sub-SAs is associated with a 3-input AND function;
a third sub-SA of the one or more sub-SAs is associated with a 3-input MAJORITY function; and
the processing output comprises an addition output or a subtraction output.

18. The method of claim 17, wherein:
the processing output comprises a SUM output and a CARRY output;
the third sub-SA is configured to generate the carry output;
the first sub-SA is configured to generate the SUM output when the CARRY output is 0; and
the second sub-SA is configured to generate the SUM output when the CARRY output is 1.

19. The method of claim 18, wherein a sub-SA of the one or more sub-SAs is associated with a two-input XNOR function and/or a three-input XOR function.

20. The method of claim 13, wherein comparing the one or more values occurs within a single memory cycle of the non-volatile memory device.
